(19) United States
(12) Patent Application Publication
(10) Pub. No.: US 2016/0126437 A1
(43) Pub. Date: May 5, 2016

(54) LIGHT-EMITTING DEVICE

(71) Applicant: SEOUL SEMICONDUCTOR CO., LTD., Ansan-si (KR)

(72) Inventors: Jae Hyun PARK, Ansan-si (KR); Byung Ki PYO, Ansan-si (KR)

(21) Appl. No.: 14/896,558

(22) PCT Filed: Jun. 5, 2014
(86) PCT No.: PCT/KR2014/005020

§ 371 Date: Dec. 7, 2015

(30) Foreign Application Priority Data
Jun. 7, 2013 (KR) 10-2013-0065443
Aug. 13, 2013 (KR) 10-2013-0095944
May 28, 2014 (KR) 10-2014-0064659

(51) Int. Cl. H01L 33/64; H01L 33/62; H01L 33/54; H01L 33/50; H01L 33/60; H01L 33/58

(52) U.S. Cl. CPC H01L 33/647; H01L 33/60; H01L 33/58; H01L 33/54; H01L 33/502; H01L 33/62

(57) ABSTRACT

The present invention discloses a light-emitting device which maximizes the optical efficiency and heat-radiation as well as facilitates thin film-type manufacture. The disclosed light-emitting device includes a film including a plurality of holes, upper conductive patterns for covering the plurality of holes, lower conductive patterns extended from the upper conductive pattern so as to be received in the holes, a bridge part for connecting adjacent upper conductive patterns, and a light-emitting diode chip installed in each of the upper conductive patterns, so that the device may be embodied in a thin film-type as well as maximizes the optical efficiency and heat-radiation, providing an advantage of reduced manufacturing time and cost.

### CROSS-REFERENCE TO RELATED APPLICATIONS

This application is the National Stage of International Patent Application No. PCT/KR2014/005020, filed on Jun. 5, 2014, and claims priority from Korean Patent Application No. 10-2013-0065443, filed on Jun. 7, 2013, Korean Patent Application No. 10-2013-0095944, filed on Aug. 13, 2013, and Korean Patent Application No. 10-2014-0064659, filed on May 28, 2014, all of which are incorporated by reference for all purposes as if fully set forth herein.

### BACKGROUND

1. Field

Exemplary embodiments relate to a light emitting device, and more particularly to a light emitting device that can maximize luminous efficacy and heat dissipation and can be easily fabricated in a thin structure.

2. Discussion of the Background

A light emitting diode chip is an electroluminescent device configured to emit light upon application of forward voltage. Compound semiconductors such as indium phosphide (InP), gallium arsenide (GaAs), gallium phosphide (GaP) and the like are used as materials for light emitting diode chips emitting red or green light, and a gallium nitride(GaN)-based compound semiconductor is used as a material for light emitting diodes emitting UV light and blue light.

Such light emitting diode chips have been used in various displays, light sources for backlight units, and the like, and applications thereof have expanded to lighting apparatuses based on use of three light emitting diode chips capable of emitting red, green and blue light, or based on development of a white light emitting diode chip capable of emitting white light through wavelength conversion by phosphors.

A general light emitting diode chip is mounted on a recess region defined by partitions on a substrate including a lead frame, and the recess region is filled with an encapsulation member containing phosphors to form a single light emitting package.

Then, a plurality of light emitting packages is mounted on a single circuit board to constitute a single light emitting device.

However, since such a general light emitting device is fabricated by manufacturing a substrate including partitions and a lead frame and then mounting light emitting diode chips on the substrate to form light emitting packages, followed by mounting the light emitting packages on a circuit board, there are problems of a complicated manufacturing process and a limit in manufacture of a thin light emitting device. Moreover, such a general light emitting device requires manufacture of the partitions and the substrate on the metal lead frame using a molding resin, and thus suffers from structural defects caused by moisture infiltration due to deterioration in surface adhesion.

### SUMMARY

Exemplary embodiments provide a light emitting device that can maximize luminous efficacy and heat dissipation and can be easily fabricated in a thin structure.

Exemplary embodiments provide a light emitting device capable of reducing manufacturing costs.

In accordance with one exemplary embodiment, a light emitting device includes a film including a plurality of holes; conductive upper patterns covering the plurality of holes; conductive lower patterns extending from the conductive upper patterns and received in the holes; a bridge connecting adjacent conductive upper patterns to each other; and a light emitting diode chip mounted on each of the conductive upper patterns.

The plurality of holes may be arranged in a matrix form on the film.

The bridge may connect the conductive upper patterns adjacent each other in a first direction to each other, and the conductive upper patterns adjacent each other in a second direction perpendicular to the first direction may be separated a predetermined distance from each other.

The film may be composed of a plurality of unit cells; the conductive upper patterns may include first and second conductive upper patterns, the first and second conductive upper patterns being separated from each other with reference to one unit cell, the first and second conductive upper patterns being shared by unit cells adjacent each other in the second direction.

The light emitting device may further include a reflective unit covering the film exposed between the first and second conductive upper patterns separated from each other, the bridge, and portions of upper surfaces of the first and second conductive upper patterns, and a lens unit disposed on the reflective unit.

The light emitting device may further include a protrusion formed on the reflective unit to define a formation region of the lens unit.

The protrusion may be composed of a plurality of layers having gradually decreasing areas from a lowermost layer to an uppermost layer and may have a stepped inner side surface.

The light emitting device may further include a molding unit within the protrusion, and the molding unit may further include a fluorescent material.

A width of the bridge may be the same or smaller than the width of the conductive upper pattern in the second direction and be greater than a radius of the lens unit.

The conductive lower pattern includes first and second regions having different widths in the second direction.

The second region may have a greater width than the first region, the width of the first region may be 80% or more the width of the second region, and the first region may be a region in which the light emitting diode chip is mounted.

The conductive upper pattern and the conductive lower pattern may be exposed to both side surfaces corresponding to a second direction of a unit cell light emitting device.

The bridge may be exposed to other side surfaces corresponding to a first direction of a unit cell light emitting device, and the bridge and the conductive upper pattern may be connected to each other along an edge of the unit cell light emitting device.

The film may be composed of a plurality of unit cells, the plurality of holes may include a pair of first and holes in each unit cell, the conductive upper patterns may include first and second conductive upper patterns, the first and second conductive upper patterns may have a boundary region in which the first and second conductive upper patterns are separated from each other with reference to one unit cell, and the boundary region may be disposed between the first and second holes.

The boundary region may be formed in a direction horizontal to a diagonal direction within the one unit cell.

The first hole may have three inner side surfaces and the second hole may have five inner side surfaces.

In accordance with another exemplary embodiment of the present disclosure, a light emitting device may include a first conductive lower pattern and a second conductive lower pattern separated from each other in a first direction; a first conductive upper pattern and a second conductive upper pattern disposed on the first conductive lower pattern and the second conductive lower pattern, respectively; an insulator disposed between the first conductive lower pattern and the second conductive lower pattern; a first bridge extending from the first conductive upper pattern in a second direction perpendicular to the first direction; a second bridge extending from the second conductive upper pattern in the second direction; and a light emitting diode chip mounted on the first conductive upper pattern.

The light emitting device may further include a reflective unit partially covering the first bridge, the second bridge, and the first conductive upper pattern and the second conductive upper pattern, and a lens unit disposed on the reflective unit.

Widths of the first bridge and the second bridge may be the same or smaller than the widths of the first and second conductive upper patterns, respectively, in the first direction, and may be smaller than a radius of the lens unit.

The second conductive lower pattern may include a first region and a second region having different areas in the first direction, the first and second regions may have different widths in the second direction, the width of the second region may be greater than the width of the first region, the width of the first region may be 80% or more the width of the second region, and the light emitting diode chip may be mounted on a region thereof overlapping the first region.

The first conductive upper pattern, the second conductive upper pattern, the first conductive lower pattern and the second conductive lower pattern may have side surfaces exposed to both side surfaces corresponding to the first direction.

An exposed side surface of the first bridge may be connected to an exposed side surface of the first conductive upper pattern, and an exposed side surface of the second bridge may be connected to an exposed side surface of the first conductive upper pattern.

According to exemplary embodiments, the light emitting device can realize a thin structure by a structure that includes a film including a plurality of holes, conductive upper patterns formed on the film, conductive lower patterns formed under the conductive upper pattern inside the plurality of holes, and a light emitting diode chip mounted on each of the conductive upper patterns.

In addition, since the conductive upper patterns are formed on the film and the plurality of holes is filled with the conductive lower patterns, the light emitting device according to exemplary embodiments can prevent failure due to infiltration of moisture or foreign matter through a space between a lead frame and an insulating substrate of a typical light emitting device.

Further, the light emitting device according to exemplary embodiments allows heat generated from light emitting diode chips to be easily discharged through the conductive upper patterns and the conductive lower patterns, thereby securing excellent heat dissipation efficiency.

Further, the light emitting device according to exemplary embodiments has a simple structure in which the light emitting diode chips are directly mounted on the conductive upper patterns of the film, and then the lens unit is formed to cover the corresponding light emitting diode chip, thereby reducing manufacturing costs and time through simplification of the structure.

A light emitting device according to a second exemplary embodiment includes conductive upper patterns divided into first and second conductive upper patterns in each unit cell, and conductive lower pattern divided into first and second conductive lower patterns, in which a light emitting diode chip is mounted on the first conductive upper pattern, thereby realizing a thin structure of the light emitting device.

Furthermore, in the light emitting device according to the second exemplary embodiment, the first and second conductive upper patterns are connected to each other by a bridge such that a region for each of the first and second conductive lower patterns and a cutting region are separated a predetermined distance from each other, thereby allowing easy cutting operation.

Furthermore, in the light emitting device according to exemplary embodiments, the film is disposed to surround the first and second conductive lower patterns such that the first and second conductive lower patterns are not exposed outside the film in order to prevent moisture infiltration and deformation by external force, thereby improving reliability.

Furthermore, the light emitting device according to exemplary embodiments further includes a bridge in a second direction of the first and second conductive upper patterns in order to prevent deterioration in electrical characteristics such as line resistance during a plating process for formation of the first and second conductive lower patterns, whereby the first and second conductive lower patterns can be formed to have a uniform thickness.

Furthermore, the light emitting device according to exemplary embodiments has improved light extraction efficiency by the structure of the protrusion composed of a plurality of layers.

### BRIEF DESCRIPTION OF THE DRAWINGS

FIG. 1 is a plan view of a light emitting device according to a first exemplary embodiment.

FIG. 2 is a plan view of a unit cell light emitting device divided by a unit cell cutting process.

FIG. 3 is a cross-sectional view taken along line I-I′ of FIG. 1.

FIG. 4 is a plan view of a light emitting device according to a second exemplary embodiment.

FIG. 5 is a cross-sectional view taken along line II-II′ of FIG. 4.

FIG. 6 is a sectional view of a light emitting device according to a third exemplary embodiment.

FIG. 7 is a plan view of a light emitting device according to a fourth exemplary embodiment.

FIG. 8 is a plan view of a unit cell light emitting device divided by a unit cell cutting process.

FIG. 9 is a plan view of a light emitting device according to a fifth exemplary embodiment.

FIG. 10 is a plan view of a unit cell light emitting device divided by a unit cell cutting process.

### DETAILED DESCRIPTION OF THE ILLUSTRATED EMBODIMENTS

Hereinafter, exemplary embodiments of the present disclosure will be described in detail with reference to the accompanying drawings. The following embodiments are provided by way of example so as to fully convey the spirit of the present disclosure to those skilled in the art to which the present disclosure pertains. Accordingly, the present disclosure is not limited to the embodiments disclosed herein and can also be implemented in different forms. In the drawings, widths, lengths, thicknesses, and the like of elements can be exaggerated for clarity and descriptive purposes. Throughout the specification, like reference numerals denote like elements having the same or similar functions.

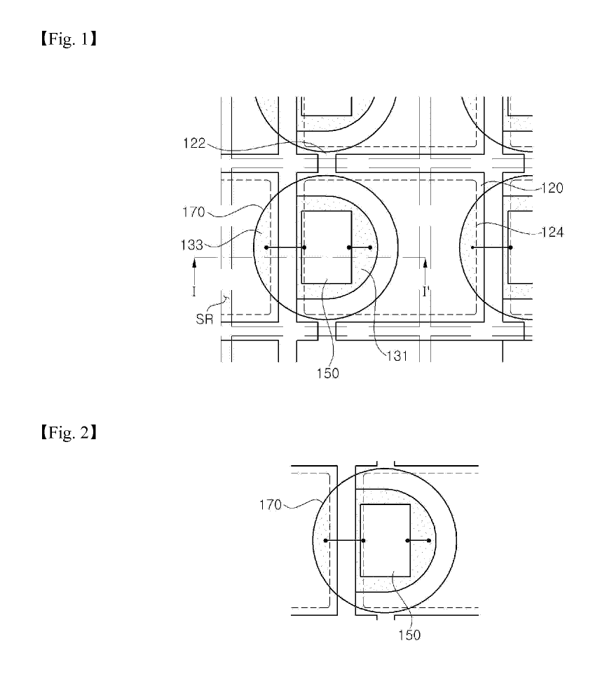

FIG. 1 is a plan view of a light emitting device according to a first exemplary embodiment and FIG. 2 is a plan view of a unit cell light emitting device divided by a unit cell cutting process.

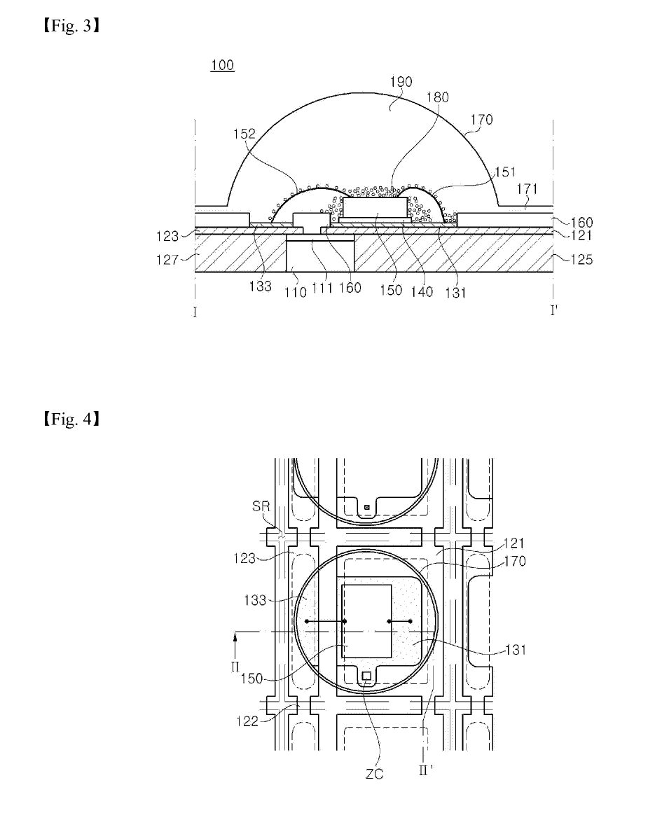

FIG. 3 is a cross-sectional view taken along line I-I′ of FIG. 1.

Referring to FIG. 1 to FIG. 3, the light emitting device according to the first exemplary embodiment has a structure in which a plurality of cells is connected to each other.

The light emitting device includes a film having a plurality of holes, a plurality of conductive upper patterns 120, a plurality of conductive lower patterns 124, a plurality of light emitting diode chips 150, a reflective unit 160, and a plurality of lens units 170.

The film includes an insulation layer 110 and a first bonding layer 111. The film has a matrix structure that surrounds the plurality of holes. The film may be formed by a mechanical punching process.

The conductive upper patterns 120 cover the holes, extend to an upper surface of the film, and include a bridge 122 that connects the conductive upper patterns 120 adjacent each other in a first direction to each other. The conductive upper patterns 120 are separated a predetermined distance from each other in a second direction perpendicular to the first direction, and the conductive upper patterns 120 adjacent each other in the second direction may be insulated from each other by the film.

Although the bridge 122 is formed to connect the conductive upper patterns 120 adjacent each other in the first direction to each other in the first exemplary embodiment, it should be understood that the present disclosure is not limited thereto, and that the light emitting device may further include a bridge for connecting the conductive upper patterns 120 adjacent each other in the second direction to each other in order to allow stable supply of examination signals to the entire light emitting diode chips 150 during an examination process.

The conductive upper patterns 120 include first and second conductive upper patterns 121, 123 shared by adjacent unit cells, and the first and second conductive upper patterns 121, 123 shared by the adjacent unit cells may be divided by a cutting process.

The conductive lower patterns 124 may be formed within the plurality of holes. The conductive lower patterns 124 may be formed by a plating process on lower surfaces of the conductive upper patterns 120. The conductive lower patterns 124 have a narrower area than the conductive upper patterns 120.

The reflective unit 160 partially covers the film and the conductive upper patterns 120. Specifically, the reflective unit 160 is formed on a region of the film exposed between the conductive upper patterns 120. Further, the reflective unit 160 may be formed on the conductive upper patterns 120 excluding regions on which the light emitting diode chips 150 of the conductive upper patterns 120 are mounted and regions electrically connected to electrodes of the light emitting diode chips 150.

The reflective unit 160 may be formed of a resin containing a reflective material having high reflectivity.

The reflective unit 160 may be formed by any method known in the art, and may be formed by, for example, a printing process. Thus, the reflective unit 160 has a constant thickness from surfaces of the film and the conductive upper patterns 120.

The light emitting diode chip 150 is disposed on each of the conductive upper patterns 120, particularly, near one edge of the conductive upper pattern 120. The light emitting diode chip 150 includes electrodes, which are electrically connected to the corresponding conductive upper pattern 120 via first and second wires 151, 152. Although the electrodes of the light emitting diode chip 150 are electrically connected to the conductive upper pattern 120 via the first and second wires 151, 152 in this exemplary embodiment, it should be understood that the present disclosure is not limited thereto and other types of light emitting diode chips, such as a vertical type light emitting diode chip employing a single wire, may also be used.

The light emitting device has a scribing region (SR) in matrix form in order to divide a unit cell light emitting device through the cutting process.

Referring to FIGS. 2 and 3, the light emitting device may be divided into a unit cell light emitting device 100 through the cutting process.

The unit cell light emitting device 100 includes a film, a light emitting diode chip 150, first and second conductive upper patterns 121, 123, first and second conductive lower patterns 125, 127, a reflective unit 160, and a lens unit 170.

The film includes an insulation layer 110 and a first bonding layer 111. The first bonding layer 111 is disposed on the insulation layer 110.

The first and second conductive upper patterns 121, 123 are disposed on the first bonding layer 111. The first and second conductive upper patterns 121, 123 may be copper patterns, without being limited thereto.

First and second protective layers 131, 133 may be formed on the first and second conductive upper patterns 121, 123, respectively. The first and second protective layers 131, 133 protect the first and second conductive upper patterns 121, 123 to prevent deformation of characteristics due to contact with air, for example, corrosion. The first and second protective layers 131, 133 may be formed of a material capable of reflecting light. The first and second protective layers 131, 133 have an additional function of reflecting light, and may be formed of, for example, Ag/Ni, without being limited thereto.

The first conductive lower pattern 125 is formed under the first conductive upper pattern 121. The first conductive lower pattern 125 may be formed by plating. That is, the first conductive lower pattern 125 may be formed on a lower surface of the first conductive upper pattern 121. Further, the first conductive lower pattern 125 may extend to a region corresponding to a lower surface of the film.

The second conductive lower pattern 127 may be formed under the second conductive upper pattern 123. The second conductive lower pattern 127 may be formed by plating. That is, the second conductive lower pattern 127 may be formed on a lower surface of the second conductive upper pattern 123. Further, the second conductive lower pattern 127 may extend to a region corresponding to the lower surface of the film.

The light emitting diode chip 150 is disposed on the first conductive upper pattern 121. The light emitting diode chip 150 may be mounted on the first conductive upper pattern 121 via a second bonding layer 140.

The light emitting diode chip 150 includes electrodes (not shown). One of the electrodes is electrically connected to the first conductive upper pattern 121 via the first wire 151, and the other electrode is electrically connected to the second conductive upper pattern 123 via the second wire 152.

A fluorescent material 180 is deposited on the light emitting diode chip 150. The fluorescent material 180 may be deposited on the light emitting diode chip 150 by spraying.

Although the fluorescent material 180 is deposited by spraying in the first exemplary embodiment, it should be understood that the present disclosure is not limited thereto and that the fluorescent material 180 may be deposited by spin coating, electrostatic deposition, electrophoretic deposition, and the like.

The first protective layer 131 may be disposed between the second bonding layer 140 and the first conductive upper pattern 121. That is, the second bonding layer 140 may be disposed between the light emitting diode chip 150 and the first protective layer W1 (131) disposed on the first conductive upper pattern 121.

The reflective unit 160 is formed on the first bonding layer 111 of the film exposed between the first and second conductive upper patterns 121, 123, and on portions of upper surfaces of the first and second conductive upper patterns 121, 123. Here, the reflective unit 160 may include a reflective material having high reflectivity or may be formed of a resin having high reflectivity.

The lens unit 170 covers the light emitting diode chip 150 and is disposed on the reflective unit 160. The lens unit 170 is formed of a light transmitting material and may further include an extension 171 covering the reflective unit 160 along an edge thereof. The extension 171 may be formed of a light transmitting material, for example, silicone.

Referring to FIG. 1 to FIG. 3, in a method of manufacturing the light emitting device, a first bonding layer 111 is formed on an insulation layer 110 and a plurality of holes is formed by punching in a first step.

In a second step, a metal layer is formed to cover the plurality of holes and first and second conductive lower patterns 125, 127 are formed under the metal layer by plating.

In a third step, first and second conductive upper patterns 121, 123 are formed to expose a portion of the first bonding layer 111 by patterning the metal layer. Here, the exposed first bonding layer 111 defines a border between the first and second conductive upper patterns 121, 123.

In a fourth step, a reflective unit 160 is formed by depositing a resin including a reflective material having high reflectivity onto the first and second conductive upper patterns 121, 123 and the exposed first bonding layer 111, followed by patterning.

In a fifth step, first and second protective layers 131, 133 are formed on the first and second conductive upper patterns 121, 123 exposed through the reflective unit 160, respectively.

In a sixth step, a light emitting diode chip 150 is mounted on the first conductive upper pattern 121 via a second bonding layer 140, and is then electrically connected to the first and second conductive upper patterns 121, 123 via first and second wires 151, 152.

In a seventh step, a fluorescent material 180 is sprayed onto the light emitting diode chip 150.

Here, the fluorescent material 180 may be restrictively formed around the light emitting diode chip 150 using a mask (not shown). The fluorescent material 180 has a uniform overall thickness.

In an eighth step, a lens unit 170 is formed to cover the light emitting diode chip 150.

Although the fluorescent material 180 is illustrated as being directly formed on the light emitting diode chip 150 in the first exemplary embodiment, it should be understood that the present disclosure is not limited thereto, and the fluorescent material 180 is dispersed within the lens unit 170 or may be formed on a surface of the lens unit 170. Herein, the fluorescent material formed within or on the surface of the lens unit 170 has a uniform overall thickness.

As described above, the light emitting device according to exemplary embodiments of the present disclosure can realize a thin structure by the substrate structure that includes the film including the plurality of holes formed therein, the conductive upper patterns 120 formed on the film, and the conductive lower patterns 124 formed under the conductive upper pattern 120 inside the plurality of holes.

In addition, since the conductive upper patterns 120 are formed on the film and the plurality of holes is filled with the conductive lower patterns 124, the light emitting device according to the exemplary embodiments can prevent failure due to infiltration of moisture or foreign matter through a space between a lead frame and an insulating substrate of a typical light emitting device.

Further, the light emitting device according to the exemplary embodiments allows heat generated from light emitting diode chips 150 to be easily discharged through the conductive upper patterns 120 and the conductive lower patterns 124, thereby securing excellent heat dissipation efficiency.

Further, the light emitting device according to the exemplary embodiments has a simple structure in which the light emitting diode chips 150 are directly mounted on the conductive upper patterns 120, and then the lens unit 170 covers the corresponding light emitting diode chip 150, thereby reducing manufacturing costs and time through simplification of the structure.

FIG. 4 is a plan view of a light emitting device according to a second exemplary embodiment and FIG. 5 is a cross-sectional view taken along line II-II′ of FIG. 4.

As shown in FIG. 4 and FIG. 5, the light emitting device according to the second exemplary embodiment has the same features as the light emitting device according to the first exemplary embodiment shown in FIG. 1 to FIG. 3 excluding a film, first and second conductive upper patterns 121, 123, and a protrusion 260, and thus the same components will be indicated by the same reference numerals and detailed descriptions thereof will be omitted.

The film includes a plurality of holes such that the first and second conductive upper patterns 121, 123 are separated from each other. The first and second conductive upper patterns 121 cover the plurality of holes.

The first and second conductive upper patterns 121, 123 are separated a predetermined distance from each other between adjacent unit cells. That is, the first conductive upper patterns 121 are connected to each other in the first direction, the second conductive upper patterns 123 are connected to each other in the first direction, and the first and second conductive upper patterns 121, 123 are separated from each other in the first direction.

A light emitting diode chip 150 is mounted on the first conductive upper pattern 121. Thus, the first conductive upper pattern 121 may have a larger area than the second conductive upper pattern 123.

The protrusion 260 has a function of defining a formation region of the lens unit 170 upon formation of the lens unit 170. The protrusion 260 is formed outside the light emitting diode chip 150 to surround the light emitting diode chip 150. The protrusion 260 may be formed on a reflective layer 160. The protrusion 260 can restrict the formation region of the lens unit 170 by surface tension with a light transmitting resin.

The light emitting device may be divided into a unit cell light emitting device 200 by a unit cell cutting process.

The light emitting device according to the second exemplary embodiment includes the film including the plurality of holes formed therein, the first and second conductive upper patterns 121, 123 separated from each other between adjacent unit cells on the film, the first and second conductive lower patterns 125, 127 formed on lower surfaces of the first and second conductive upper patterns 121, 123 within the plurality of holes, and the light emitting diode chips 150 mounted on the first conductive upper pattern 121, thereby realizing a thin structure of the light emitting device.

In addition, since the first and second conductive upper patterns 121, 123 are formed on the film and the plurality of holes is filled with the first and second conductive lower patterns 125, 127, the light emitting device according to this exemplary embodiment can prevent failure due to infiltration of moisture or foreign matter through a space between a lead frame and an insulating substrate of a typical light emitting device.

Further, the light emitting device according to this exemplary embodiment allows heat generated from light emitting diode chips 150 to be easily discharged through the first and second conductive upper patterns 121, 123 and the first and second conductive lower patterns 125, 127, thereby securing excellent heat dissipation efficiency.

Further, in the light emitting device according to the second exemplary embodiment, the first and second conductive upper patterns 121, 123 are connected to each other by the bridge such that a region for each of the first and second conductive lower patterns 125, 127 and a cutting region are separated a predetermined distance from each other, thereby allowing easy cutting operation.

Furthermore, in the light emitting device according to this exemplary embodiment, the film is disposed to surround the first and second conductive lower patterns 125, 127 such that the first and second conductive lower patterns 125, 127 are not exposed outside the film in order to prevent moisture infiltration and deformation by external force, thereby improving reliability.

Furthermore, the light emitting device according to this exemplary embodiment further includes the bridge 122 in the second direction of the first and second conductive upper patterns 121, 123 in order to prevent deterioration in electrical characteristics such as line resistance during a plating process for formation of the first and second conductive lower patterns 125, 127, whereby the first and second conductive lower patterns 125, 127 can be formed to have a uniform thickness.

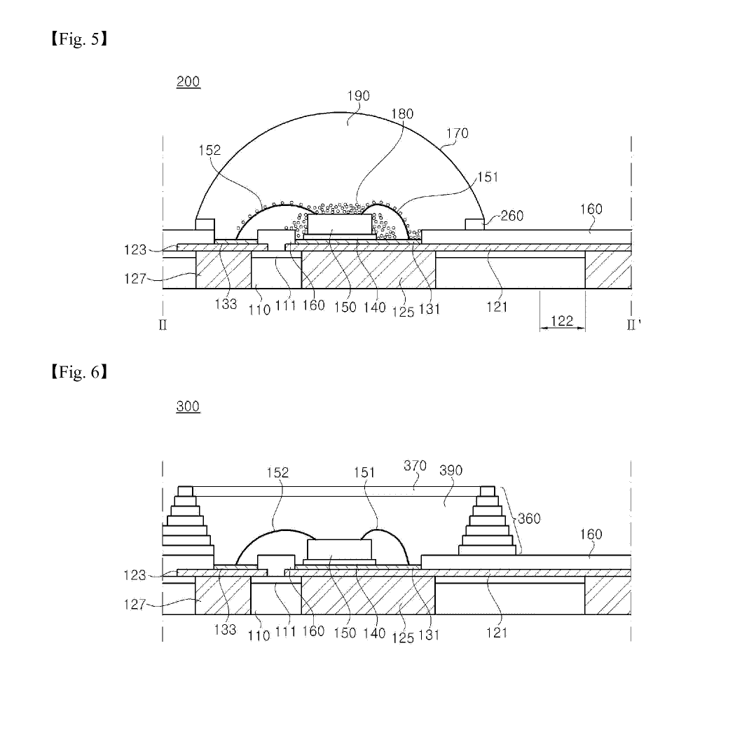

FIG. 6 is a sectional view of a light emitting device according to a third exemplary embodiment.

As shown in FIG. 6, the light emitting device according to the third exemplary embodiment has the same features as the light emitting device according to the second exemplary embodiment shown in FIG. 4 and FIG. 5 excluding a protrusion 360, a molding unit 390 and a lens unit 380, and thus the same components will be indicated by the same reference numerals and detailed descriptions thereof will be omitted.

The light emitting device may be divided into a unit cell light emitting device 300 by a unit cell cutting process.

The protrusion 360 may be composed of a plurality of layers. The protrusion 360 has a gradually decreasing area from a lowermost layer to an uppermost layer. The protrusion 360 has inner and outer side surfaces each having a stepped structure when viewed in cross-section. The inner side surface of the stepped structure has a function of improving light extraction efficiency by refracting light emitted from a light emitting diode chip 150 to the outside. The protrusion 360 may be formed on the reflective unit 160 by patterning. The protrusion 360 may include a reflective material or may be formed of a reflective resin.

The protrusion 360 acts as a dam defining a formation region of the molding unit 390.

The molding unit 390 may be formed on the light emitting diode chip 150. The molding unit 390 may be formed of a light transmitting material, for example, silicone. The molding unit 390 may be formed inside the protrusion 360.

Although the molding unit 390 is illustrated as being formed of the light transmitting material in the third exemplary embodiment, it should be understood that the present disclosure is not limited thereto and that the molding unit 390 may further include a fluorescent material.

The lens unit 380 is disposed on the molding unit 390. The lens unit 380 is supported by the molding unit 390 and the protrusion 360. The lens unit 380 may include a fluorescent material or may be formed of a fluorescent resin.

The light emitting device according to the third exemplary embodiment includes the film including the plurality of holes formed therein, the first and second conductive upper patterns 121, 123 separated from each other between adjacent unit cells on the film, the first and second conductive lower patterns 125, 127 formed on lower surfaces of the first and second conductive upper patterns 121, 123 within the plurality of holes, and the light emitting diode chips 150 mounted on the first conductive upper pattern 121, thereby realizing a thin structure of the light emitting device.

In addition, since the first and second conductive upper patterns 121, 123 are formed on the film and the plurality of holes is filled with the first and second conductive lower patterns 125, 127, the light emitting device according to this exemplary embodiment can prevent failure due to infiltration of moisture or foreign matter through a space between a lead frame and an insulating substrate of a typical light emitting device.

Further, the light emitting device according to this exemplary embodiment allows heat generated from light emitting diode chips 150 to be easily discharged through the first and second conductive upper patterns 121, 123 and the first and second conductive lower patterns 125, 127, thereby securing excellent heat dissipation efficiency.

Furthermore, the light emitting device according to this exemplary embodiment has improved light extraction efficiency by the structure of the protrusion 360 composed of the plurality of layers.

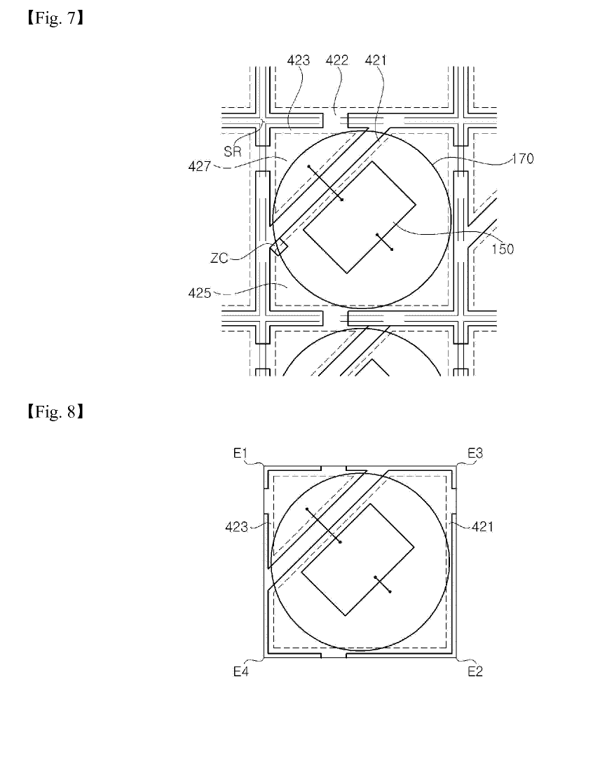

FIG. 7 is a plan view of a light emitting device according to a fourth exemplary embodiment, and FIG. 8 is a plan view of a unit cell light emitting device divided by a unit cell cutting process.

As shown in FIG. 7 and FIG. 8, the light emitting device according to the fourth exemplary embodiment has the same features as the light emitting device according to the second exemplary embodiment shown in FIG. 4 and FIG. 5 excluding first and second conductive upper patterns 421, 423, first and second conductive lower patterns 425, 427, and a bridge 422, and thus the same components will be indicated by the same reference numerals and detailed descriptions thereof will be omitted.

The light emitting device according to the fourth exemplary embodiment includes a film including a plurality of holes, and the plurality of holes includes a pair of holes having different sizes and shapes in each unit cell.

The pair of holes includes a hole having three inner side surfaces and a hole having five inner side surfaces.

The first and second conductive upper patterns 421, 423 cover the pair of holes. Specifically, the first conductive upper pattern 421 covers the hole having five inner side surfaces, and the second conductive upper pattern 423 covers the hole having three inner side surfaces. Here, although the hole having three inner side surfaces and the hole having five inner side surfaces are provided to each unit cell in the fourth exemplary embodiment, it should be understood that the present disclosure is not limited thereto and that the shapes of the holes are not particularly limited and may be changed as needed. Further, the shapes of the first and second conductive upper patterns 421, 423 may also be changed corresponding to the shapes of the holes.

The first and second conductive upper patterns 421, 423 are separated a predetermined distance from each other in a unit cell. A unit cell light emitting device divided by the cutting process has first to fourth edges E1 to E4, and a border region between the first and second conductive upper patterns 421, 423 separated from each other is disposed parallel to a first diagonal axis connecting the third and fourth edges E3 and E4 to each other. That is, the border region between the first and second conductive upper patterns 421, 423 separated from each other is disposed in a direction perpendicular to a second diagonal axis connecting the first and second edges E1 and E2 to each other. Although the border region between the first and second conductive upper patterns 421, 423 separated from each other is illustrated as being parallel to the first diagonal axis in the fourth exemplary embodiment, it should be understood that the present disclosure is not limited thereto and that the border region may be disposed parallel to the second diagonal axis.

The bridge 422 serves to connect the second conductive upper pattern 423 to the first conductive upper pattern 421. The first and second conductive upper patterns 421, 423 connected to each other by the bridge 422 are disposed on different unit cells. That is, the second conductive upper pattern 423 may be connected to the first conductive upper patterns 421 of adjacent unit cells by the bridges 422. In addition, the first conductive upper pattern 421 may be connected to the second conductive upper patterns 423 of adjacent unit cells by the bridges 422.

A light emitting diode chip 150 is mounted on the first conductive upper pattern 421. Thus, the first conductive upper pattern 421 may have a larger area than the second conductive upper pattern 423.

The light emitting device according to the fourth exemplary embodiment includes the film including the plurality of holes formed therein, the first and second conductive upper patterns 421, 423 separated from each other between adjacent unit cells on the film, and the first and second conductive lower patterns 425, 427 formed on lower surfaces of the first and second conductive upper patterns 421, 423 within the plurality of holes, thereby realizing a thin structure of the light emitting device.

In addition, since the first and second conductive upper patterns 421, 423 are formed on the film and the plurality of holes is filled with the first and second conductive lower patterns 425, 427, the light emitting device according to this exemplary embodiment can prevent failure due to infiltration of moisture or foreign matter through a space between a lead frame and an insulating substrate of a typical light emitting device.

Further, the light emitting device according to this exemplary embodiment allows heat generated from light emitting diode chips 150 to be easily discharged through the first and second conductive upper patterns 421, 423 and the first and second conductive lower patterns 425, 427, thereby securing excellent heat dissipation efficiency.

Further, in the light emitting device according to the fourth exemplary embodiment, the first and second conductive upper patterns 421, 423 are connected to each other by the bridge 422 such that a region for each of the first and second conductive lower patterns 425, 427 and a cutting region are separated a predetermined distance from each other, thereby allowing easy cutting operation.

Furthermore, the light emitting device according to this exemplary embodiment prevents deterioration in electrical characteristics such as line resistance during a plating process for formation of the first and second conductive lower patterns 425, 427, whereby the first and second conductive lower patterns 425, 427 can be formed to have a uniform thickness.

Furthermore, in the light emitting device according to this exemplary embodiment, the film is disposed to surround the first and second conductive lower patterns 425, 427 such that the first and second conductive lower patterns 425, 427 are not exposed outside the film in order to prevent moisture infiltration and deformation by external force, thereby improving reliability.

Furthermore, in the light emitting device according to the fourth exemplary embodiment, the border region between the first and second conductive upper patterns 421, 423 separated from each other in each unit cell is formed in the diagonal direction of the unit cell to secure a margin for mounting the light emitting diode chip 150 and a hole formation margin as large as possible, thereby improving reliability in mounting the light emitting diode chip 150 while maximizing heat dissipation efficiency.

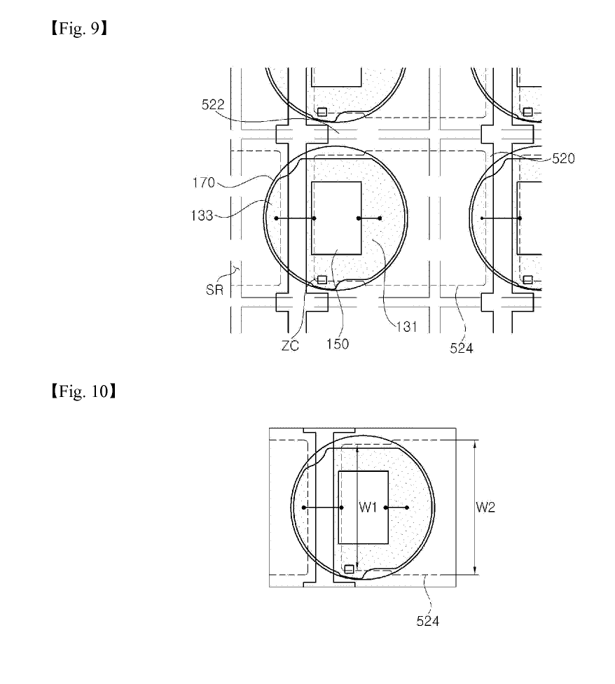

FIG. 9 is a plan view of a light emitting device according to a fifth exemplary embodiment and FIG. 10 is a plan view of a unit cell light emitting device divided by a unit cell cutting process.

As shown in FIG. 9 and FIG. 10, the light emitting device according to the fifth exemplary embodiment has the same features as the light emitting device according to the first exemplary embodiment excluding conductive upper patterns 520 and conductive lower patterns 524, and thus the same components will be indicated by the same reference numerals and detailed descriptions thereof will be omitted.

The conductive upper patterns 520 include a bridge 522 that connects the conductive upper patterns 520 adjacent each other in a first direction to each other. The conductive upper patterns 520 adjacent each other in a second direction are separated a predetermined distance from each other and insulated from each other.

Since the conductive upper patterns 520 are formed on a region exposed by the reflective unit, a Zener diode ZC is mounted within the lens unit 170 and the reflective unit may be formed so as not to overlap the region in which the Zener diode (ZC) is mounted. In the drawings, the second protective layer 133 has depressed shapes at upper and lower sides thereof.

The bridge 522 connects the conductive upper patterns 520 adjacent each other in the first direction to each other and has a function of improving pattern reliability in formation of the conductive upper patterns 520. That is, the conductive upper patterns 520 may be formed by plating and connected to each other in the first direction, thereby improving pattern reliability in a manufacturing process. The bridge 522 may have the same or smaller width than the conductive upper patterns 520 in the second direction, without being limited thereto. The bridge 522 may be designed to be greater than the radius of the lens unit 170 in the second direction. A reflective unit (not shown) is formed on the bridge 522.

The conductive lower pattern 524 has a smaller area than the conductive upper pattern 520. The conductive lower pattern 524 may be divided into first and second regions having different widths in the second direction. Here, the first region may be defined as a region in which the light emitting diode chip 150 is mounted, and the second region may be defined as a region extending from the first region to an edge. The first region has a first width W1 in the first direction and the second region has a second width W2 in the first direction. The first width W1 is smaller than the second width W2. Specifically, the first width W1 may be 80% or more the second width W2. For example, the first width W1 may be 1.77 mm and the second width W2 may be 2.17 mm. According to this exemplary embodiment, the first width W1 is designed to be 80% or more the second width W2, thereby preventing deterioration in electrical characteristics while realizing a thin structure.

In a unit cell light emitting device divided by a unit cell cutting process, the conductive upper pattern 520 and the conductive lower pattern 524 have shapes corresponding to each other and are exposed at both side surfaces thereof corresponding to the second direction.

In the unit cell light emitting device, the bridge 522 is exposed at other side surfaces corresponding to the first direction. Here, the bridge 522 may be connected to the conductive upper patterns 520 along an edge of the unit cell light emitting device.

In the light emitting device according to the fifth exemplary embodiment, the conductive lower pattern 524 is designed to have the first and second widths W1, W2 to have a larger heat dissipation area than a substrate of a typical light emitting device, thereby providing excellent heat dissipation efficiency.

Further, in the light emitting device according to the fifth exemplary embodiment, the first width W1 is designed to be 80% or more the second width W2 to increase an area of the first region in which the light emitting diode chip 150 is mounted, thereby improving reliability of an SMT process.

Furthermore, in the light emitting device according to the fifth exemplary embodiment, a difference between the first width W1 and the second width W2 is set to 20% or less, thereby improving reliability of a process of forming the conductive lower pattern 524 through plating, while improving productivity.

1. A light emitting device, comprising:
a film comprising holes;
conductive upper patterns, each of the conductive upper patterns respectively covering each of the holes;
conductive lower patterns extending from the conductive upper patterns, each of the conductive lower patterns being respectively disposed in each of the holes;
a bridge connecting adjacent conductive upper patterns to each other; and
light emitting diode chips, each of the light emitting diode chips being respectively mounted on each of the conductive upper patterns.

2. The light emitting device of claim 1, wherein the holes are arranged in a matrix on the film.

3. The light emitting device of claim 1, wherein:
the bridge connects conductive upper patterns adjacent to each other in a first direction; and
conductive upper patterns adjacent to each other in a second direction perpendicular to the first direction are separated from each other.

4. The light emitting device of claim 3, wherein:
the film comprises unit cells;
the conductive upper patterns comprise first and second conductive upper patterns;
the first and second conductive upper patterns are separated from each other with reference to one of the unit cells; and
the first and second conductive upper patterns are shared by unit cells adjacent to each other in the second direction.

5. The light emitting device of claim 4, further comprising:
a reflective unit covering a portion of the film that is exposed between the first and second conductive upper patterns, the bridge, and portions of upper surfaces of the first and second conductive upper patterns; and
a lens unit disposed on the reflective unit.

6. The light emitting device of claim 5, further comprising:
a protrusion disposed on the reflective unit, the protrusion defining a formation region of the lens unit.

7. The light emitting device of claim 5, wherein the protrusion comprises layers having gradually decreasing areas from a lowermost layer to an uppermost layer and having a stepped inner side surface.

8. The light emitting device of claim 6, further comprising:
a molding unit disposed within the protrusion, the molding unit comprising a fluorescent material.

9. The light emitting device of claim 5, wherein a width of the bridge is less than or equal to the width of the conductive upper pattern in the second direction and is greater than a radius of the lens unit.

10. The light emitting device of claim 3, wherein the conductive lower pattern comprises first and second regions having different widths in the second direction.

11. The light emitting device of claim 10, wherein:
the second region has a width greater than the width of the first region;
the width of the first region is at least 80% of the width of the second region; and
the light emitting diode chip is mounted in the first region.

12. The light emitting device of claim 1, wherein the conductive upper pattern and the conductive lower pattern are exposed to side surfaces of the light emitting device corresponding to a second direction thereof.

13. The light emitting device of claim 12, wherein:
the bridge is exposed to other side surfaces of the light emitting device corresponding to a first direction thereof; and
the bridge and the conductive upper pattern are connected to each other along an edge of the unit cell light emitting device.

14. The light emitting device of claim 1, wherein:
the film comprises unit cells;
the holes comprise a pair of first and second holes in each of the unit cells;
the conductive upper patterns comprise first and second conductive upper patterns;
the first and second conductive upper patterns each have a boundary region in which the first and second conductive upper patterns are separated from each other with reference to one of the unit cell; and
the boundary region is disposed between the first and second holes.

15. The light emitting device of claim 14, wherein the boundary region is disposed in a direction horizontal to a diagonal direction within the one unit cell.

16. The light emitting device of claim 14, wherein the first hole has three inner side surfaces and the second hole has five inner side surfaces.

17. A light emitting device, comprising:
a first conductive lower pattern and a second conductive lower pattern separated from each other in a first direction;
a first conductive upper pattern and a second conductive upper pattern disposed on the first conductive lower pattern and the second conductive lower pattern, respectively;
an insulator disposed between the first conductive lower pattern and the second conductive lower pattern;
a first bridge extending from the first conductive upper pattern in a second direction perpendicular to the first direction;
a second bridge extending from the second conductive upper pattern in the second direction; and
a light emitting diode chip mounted on the first conductive upper pattern.

18. The light emitting device of claim 17, further comprising:
a reflective unit partially covering the first bridge, the second bridge, the first conductive upper pattern, and the second conductive upper pattern; and
a lens unit disposed on the reflective unit.

19. The light emitting device of claim 17, wherein:
widths of the first bridge and the second bridge are less than or equal to widths of the first and second conductive upper patterns, respectively, in the first direction; and
the widths of the first bridge and the second bridge are greater than a radius of the lens unit.

20. The light emitting device of claim 17, wherein:
the second conductive lower pattern comprises a first region and a second region having different areas in the first direction; and
the first and second regions have different widths in the second direction, the width of the second region is greater than the width of the first region, the width of the first region is at least 80% of the width of the second region, and the light emitting diode chip is mounted on a portion thereof overlapping the first region.

21. The light emitting device of claim 17, wherein the first conductive upper pattern, the second conductive upper pattern, the first conductive lower pattern, and the second conductive lower pattern have side surfaces exposed to both side surfaces corresponding to the first direction.

22. The light emitting device of claim 17, wherein an exposed side surface of the first bridge is connected to an exposed side surface of the first conductive upper pattern, and an exposed side surface of the second bridge is connected to an exposed side surface of the first conductive upper pattern.
